(19) United States
(12) Patent Application Publication
(10) Pub. No.: US 2026/0177508 A1
(43) Pub. Date: Jun. 25, 2026

(54) BONDED WAFER METROLOGY

(71) Applicant: KLA Corporation, Milpitas, CA (US)

(72) Inventors: Avner Safrani, Misgav (IL); Andrew V. Hill, Berkley, CA (US); Dmitry Gorelik, Migdal Haemek (IL); Yoram Uziel, Migdal Haemek (IL); Yossi Golan, Milpitas, CA (US); Roman Gendelman, Milpitas, CA (US); Aviv Ish shalom, Milpitas, CA (US)

(21) Appl. No.: 18/999,649

(22) Filed: Dec. 23, 2024

(51) Int. Cl. G01N 21/956; G01N 21/88; G01N 21/95; H10D 88/00

(52) U.S. Cl. CPC G01N 21/956; G01N 21/8806; G01N 21/9501; G01N 2021/8825; H10D 88/01

(57) ABSTRACT

A metrology system may include a light source providing illumination, a single objective lens to direct the illumination to an overlay target with a top-substrate feature and a bottom-substrate feature and collect sample light from the overlay target, an adjustable illumination aperture stop to adjust an illumination numerical aperture, a detector configured to image the sample based on the sample light with both the top-substrate feature and the bottom-substrate feature within a field of view, and an adjustable collection aperture stop configured to adjust an imaging NA. The system may include a controller to receive a thickness of the top substrate, generate at least a portion of the metrology recipe defining imaging parameters providing a desired contrast, receive an image of the overlay target based on the metrology recipe, and generate an overlay measurement between the top substrate and the bottom substrate based on the image.

### TECHNICAL FIELD

The present invention relates generally to overlay metrology and, more particularly, to die two wafer (D2W) overlay metrology.

### BACKGROUND

Advanced packaging involves stacking different chips to create composite integrated circuit systems. For example, in 3D packaging, a memory chip is often bonded on top of a logic chip in a process known as hybrid bonding. As another example, multiple memory dies (e.g., DRAM, SRAM, or the like) may be stacked one on top of the other forming a memory block known as high bandwidth memory (HBM). Accurate alignment of these bonded dies is crucial for ensuring proper connectivity and functionality. Current state-of-the-art packaging requires extremely precise overlay measurements, with total measurement uncertainty (TMU) requirements as low as 15 nm for a 6 μm pitch size. Traditional methods utilizing brightfield imaging face challenges in achieving this precision due to factors like the need for large fields of view and defocus between marks, which limits the contrast and measurement precision. There is therefore a need to develop systems and methods to address the above deficiencies.

### SUMMARY

In embodiments, the techniques described herein relate to a metrology system including a light source configured to provide illumination; a single objective lens configured to direct the illumination to an overlay target on a sample and collect sample light from the overlay target, where the sample includes a top substrate and a bottom substrate, where the overlay target includes a top-substrate feature on the top substrate and a bottom-substrate feature on the bottom substrate; an adjustable illumination aperture stop configured to adjust an illumination numerical aperture (NA) of the illumination on the sample; a detector configured to image the sample based on the sample light, where both the top-substrate feature and the bottom-substrate feature of the overlay target are within a field of view of the detector; an adjustable collection aperture stop configured to adjust an imaging NA of the sample light provided to the detector; and a controller including one or more processors configured to execute program instructions causing the one or more processors to implement a metrology recipe by receiving a thickness of the top substrate; generating at least a portion of the metrology recipe defining at least a position of the single objective lens relative to the sample, a configuration of the adjustable collection aperture stop, and a configuration of the adjustable illumination aperture stop based on the thickness of the top substrate to simultaneously image the top-substrate feature and the bottom-substrate feature in a single image, where the metrology recipe provides a contrast of the top-substrate feature and the bottom-substrate feature in the single image according to a contrast metric; receiving an image of the overlay target based on the metrology recipe; and generating an overlay measurement between the top substrate and the bottom substrate based on the image.

In embodiments, the techniques described herein relate to a metrology system, where the one or more processors of the controller are further configured to receive one or more additional images of one or more additional overlay targets based on the metrology recipe; and generate one or more additional overlay measurements of the one or more additional overlay targets based on the one or more additional images.

In embodiments, the techniques described herein relate to a metrology system, where generating the metrology recipe includes evaluating two or more test images generated at different values of at least one of the position of the single objective lens relative to the sample, the configuration of the adjustable collection aperture stop, or the configuration of the adjustable illumination aperture stop.

In embodiments, the techniques described herein relate to a metrology system, where the two or more test images include at least one brightfield image and at least one darkfield image.

In embodiments, the techniques described herein relate to a metrology system, where the single image is a brightfield image.

In embodiments, the techniques described herein relate to a metrology system, where the single image is a darkfield image.

In embodiments, the techniques described herein relate to a metrology system, where the bottom-substrate feature is laterally displaced from the top-substrate feature.

In embodiments, the techniques described herein relate to a metrology system, where the bottom-substrate feature is exposed.

In embodiments, the techniques described herein relate to a metrology system, where the bottom-substrate feature is covered by the top substrate.

In embodiments, the techniques described herein relate to a metrology system, where the bottom-substrate feature is covered by a dummy substrate.

In embodiments, the techniques described herein relate to a metrology system, where the top-substrate feature and the bottom-substrate feature are at least partially overlapping.

In embodiments, the techniques described herein relate to a metrology system, where receiving the thickness of the top substrate includes receiving the thickness of the top substrate from at least one of a user, a sensor in the metrology system, or an external system.

In embodiments, the techniques described herein relate to a metrology system, further including a focus system including an additional lens and an additional detector.

In embodiments, the techniques described herein relate to a metrology system, where the focus system includes a Linnik interferometer.

In embodiments, the techniques described herein relate to a metrology system, where receiving the thickness of the top substrate includes measuring the thickness of the top substrate from at least one of a user or an external system with the focus system.

In embodiments, the techniques described herein relate to a metrology system, further including a filter to adjust a spectrum of the illumination.

In embodiments, the techniques described herein relate to a metrology system including a light source configured to provide an illumination; a single objective lens configured to direct the illumination to an overlay target on a sample and collect sample light from the overlay target, where the sample includes a top substrate and a bottom substrate, where the overlay target includes a top-substrate feature on the top substrate and a bottom-substrate feature on the bottom substrate; an adjustable illumination aperture stop configured to adjust an illumination NA (numerical aperture) of the illumination on the sample; one or more detectors configured to image the sample based on the sample light, where both the top-substrate feature and the bottom-substrate feature of the overlay target are within a field of view of the one or more detectors; an adjustable collection aperture stop configured to adjust an imaging NA of the sample light provided to the one or more detectors; a linear translation stage to adjust a position of the single objective lens relative to the sample along a focal direction, where an imaged lateral motion of the linear translation stage in a plane orthogonal to the focal direction is lower than an overlay measurement tolerance; a controller including one or more processors configured to execute program instructions causing the one or more processors to implement a metrology recipe by receiving a thickness of the top substrate; generating at least a portion of the metrology recipe defining at least the position of the single objective lens relative to the sample, a configuration of the adjustable collection aperture stop, and a configuration of the adjustable illumination aperture stop based on the thickness of the top substrate to separately image the top-substrate feature and the bottom substrate in a first image and a second image, where the metrology recipe provides a contrast of the top-substrate feature and the bottom-substrate feature in the first image and the second image according to a contrast metric; receiving the first image and the second image of the overlay target based on the metrology recipe; and generating an overlay measurement between the top substrate and the bottom substrate based on the first image and the second image.

In embodiments, the techniques described herein relate to a metrology system, where the first image and the second image are generated by a single detector of the one or more detectors at different settings of the linear translation stage.

In embodiments, the techniques described herein relate to a metrology system, where the one or more detectors include a first detector to generate the first image and a second detector to generate the second image, where at least one of the first detector or the second detector is mounted on an additional linear translation stage, where an imaged lateral motion of the additional linear translation stage in a plane orthogonal to an optical axis is lower than the overlay measurement tolerance.

In embodiments, the techniques described herein relate to a metrology system, where generating the metrology recipe includes evaluating test images generated at different values of at least one of the position of the single objective lens relative to the sample, the configuration of the adjustable collection aperture stop, or the configuration of the adjustable illumination aperture stop.

In embodiments, the techniques described herein relate to a metrology system, where the test images include at least one brightfield image and at least one darkfield image.

In embodiments, the techniques described herein relate to a metrology system, where the first image and the second image are brightfield images.

In embodiments, the techniques described herein relate to a metrology system, where the first image and the second image are darkfield images.

In embodiments, the techniques described herein relate to a metrology system, where the bottom-substrate feature is laterally displaced from the top-substrate feature.

In embodiments, the techniques described herein relate to a metrology system, where the bottom-substrate feature is exposed.

In embodiments, the techniques described herein relate to a metrology system, where the bottom-substrate feature is covered by the top substrate.

In embodiments, the techniques described herein relate to a metrology system, where the bottom-substrate feature is covered by a dummy substrate.

In embodiments, the techniques described herein relate to a metrology system, where the top-substrate feature and the bottom-substrate feature are at least partially overlapping.

In embodiments, the techniques described herein relate to a metrology system, where receiving the thickness of the top substrate includes receiving the thickness of the top substrate from at least one of a user, a sensor in the metrology system, or an external system.

In embodiments, the techniques described herein relate to a metrology system, further including a focus system including an additional lens and an additional detector.

In embodiments, the techniques described herein relate to a metrology system, where the focus system includes a Linnik interferometer.

In embodiments, the techniques described herein relate to a metrology system, where receiving the thickness of the top substrate includes measuring the thickness of the top substrate from at least one of a user or an external system with the focus system.

In embodiments, the techniques described herein relate to a metrology system, further including a filter to adjust a spectrum of the illumination.

In embodiments, the techniques described herein relate to a metrology system, where the linear translation stage includes an air bearing stage.

In embodiments, the techniques described herein relate to a metrology method including illuminating an overlay target on a sample with an objective lens with an illumination, where the sample includes a top substrate and a bottom substrate, where the overlay target includes a top-substrate feature on the top substrate and a bottom-substrate feature on the bottom substrate that is laterally displaced from the top-substrate feature in a location not covered by the top substrate; determining a thickness of the top substrate; setting a focal plane of the objective lens, an illumination NA (numerical aperture) of the illumination, and an imaging NA of sample light collected by the objective lens and directed to a detector for imaging the sample to place both the top-substrate feature and the bottom-substrate feature within a depth of field of the objective lens; generating an image of the overlay target with the detector; and generating an overlay measurement between the top substrate and the bottom substrate based on the image.

In embodiments, the techniques described herein relate to a metrology method, where generating the image of the overlay target with the detector includes generating the image as a brightfield image.

In embodiments, the techniques described herein relate to a metrology method, where generating the image of the overlay target with the detector includes generating the image as a darkfield image.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A illustrates a block diagram of an overlay metrology system, in accordance with one or more embodiments of the present disclosure.

FIG. 1B illustrates a conceptual view of a configuration of the overlay metrology system including a single detector, in accordance with one or more embodiments of the present disclosure.

FIG. 1C illustrates a conceptual view of a configuration of the overlay metrology system including two detectors, in accordance with one or more embodiments of the present disclosure.

FIG. 1D illustrates a conceptual view of a configuration of the overlay metrology system providing double telecentric of both object and image space, in accordance with one or more embodiments of the present disclosure.

FIG. 1E illustrates a relationship between image and focus planes in the overlay metrology system, in accordance with one or more embodiments of the present disclosure.

FIG. 2A illustrates a conceptual side view of an overlay target, in accordance with one or more embodiments of the present disclosure.

FIG. 2B illustrates a variation of FIG. 2A depicting conditions for simultaneous imaging of both the top-substrate features and the bottom-substrate features on a single detector in a single grab, in accordance with one or more embodiments of the present disclosure.

FIG. 3 illustrates a series of schematic diagrams depicting images of top-substrate features and bottom-substrate features of a side by side (SBS) overlay target as a function of imaging numerical aperture and thickness of the top substrate, in accordance with one or more embodiments of the present disclosure.

FIG. 4A illustrates a brightfield image of an SBS overlay target generated using a single-grab imaging technique, in accordance with one or more embodiments of the present disclosure.

FIG. 4B illustrates a darkfield image of the same SBS overlay target images in FIG. 4A using a single-grab imaging technique, in accordance with one or more embodiments of the present disclosure.

FIG. 4C illustrates double-grab imaging of an SBS overlay target, in accordance with one or more embodiments of the present disclosure.

FIG. 5 is a flow diagram illustrating steps performed in an overlay metrology method, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing bonded sample overlay measurements of overlay targets with a wide range of die thicknesses in which one or more features are buried beneath at least a portion of a substrate. For example, a bonded sample may include two bonded substrates such as, but not limited to, a die-to-wafer (D2W) sample or a wafer-to-wafer (W2W) sample.

For example, systems and methods disclosed herein may be suitable for, but not limited to, overlay measurements on a side-by-side (SBS) overlay target. As an illustration, a SBS overlay target suitable for an overlay measurement between a top substrate (e.g., a die, a wafer, or any other suitable substrate) and a bottom substrate (e.g., a wafer) may include a top-substrate feature on the top substrate at least partially buried beneath the top substrate, as well as a bottom-substrate feature on the bottom substrate (e.g., a wafer). The top-substrate feature and the bottom-substrate feature may further be laterally displaced, where this lateral displacement may be referred to as a mark-to-mark (M2M) distance. In some cases, the bottom-substrate feature is exposed to air. In some cases, the bottom-substrate feature is buried beneath a dummy substrate. As another example, systems and methods disclosed herein may be suitable for, but not limited to, overlay measurements on an overlay target in which the top-substrate feature and the bottom-substrate feature are at least partially overlapping.

It is contemplated herein that bonded sample overlay measurements present multiple challenges. For example, the top-substrate feature and the bottom-substrate feature may be separated by a large axial distance, which may require a relatively large depth of field. An SBS target may further provide substantially different optical paths to the first-substrate and second-substrate features with the first-substrate feature buried beneath the first substrate near a bonding interface and the second-substrate feature exposed to air, which may place additional constraints on the depth of field. As another example, the lateral displacement of the top-substrate feature and the bottom-substrate feature in an SBS overlay target requires a relatively large field of view to simultaneously image both features. These challenges taken together tend to require smaller numerical aperture (NA) values and can result in low contrast and correspondingly low robustness to the overlay measurements.

In embodiments, an overlay metrology system provides a single objective lens and an adjustable numerical aperture for collection and/or illumination light that is used to tailor the collection and/or illumination NA based on the particular thickness of the first substrate. Such a configurable overlay metrology system may thus provide the highest NA suitable for each particular sample. Additionally, illumination and/or collection apertures may be used to implement darkfield imaging, brightfield imaging, or enable flexible selection of the imaging configuration. Such a configuration in which the illumination and/or imaging NA may be adjustable with a single objective lens may provide greater flexibility and customizability than alternative solutions that utilize multiple objective lenses (e.g., on a turret) to provide adjustability of illumination and/or imaging NA. For example, adjusting the illumination and/or imaging NA by swapping out objective lenses may limit potential values of the illumination and/or imaging NA to a series of fixed values, whereas the systems and methods disclosed herein may provide potentially any combination of illumination NA and imaging NA obtainable with a particular objective lens. As another example, adjusting the illumination and/or imaging NA by swapping out objective lenses may introduce matching and/or alignment errors.

The systems and methods disclosed herein may further be suitable for either single-grab or double-grab measurement techniques.

A single-grab technique may provide simultaneous imaging of both the first-substrate feature and the second-substrate feature using either a single detector or multiple detector. A single-detector single-grab technique may position the sample at a pool focus position at which the first-substrate feature and the second-substrate feature are both simultaneously in focus. A double-detector single-grab technique may utilize two detectors in different imaging channels to simultaneously image the first-substrate feature and the second-substrate feature. This configuration may enable tailoring the NA for imaging one or both features.

A double-grab technique may provide sequential imaging of both the first-substrate feature and the second substrate feature. For example, various components of the overlay metrology system may be mounted on a high-stiffness translation stage such as, but not limited to, an air-bearing stage to enable sequential imaging of different field planes. This configuration may also enable tailoring the NA for imaging one or both features.

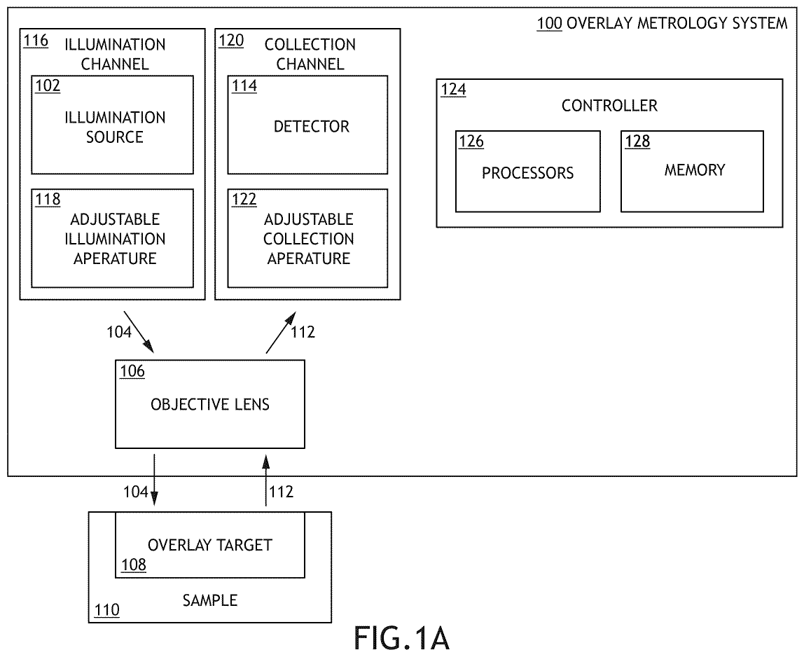

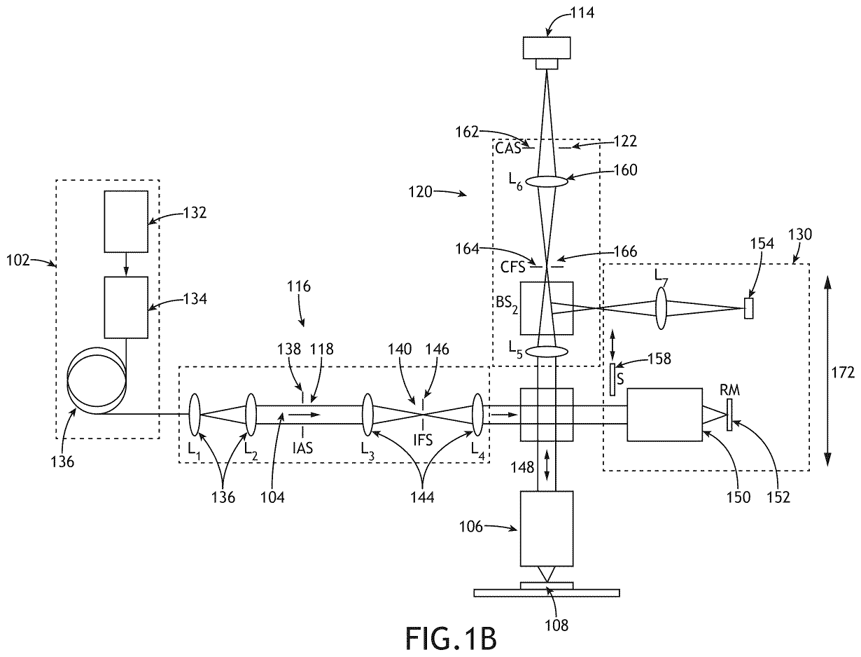

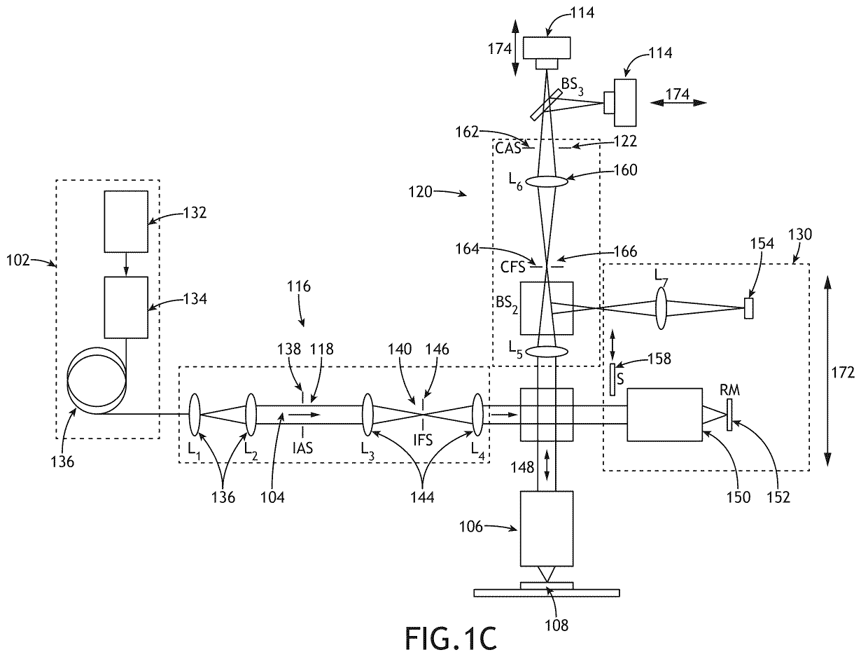

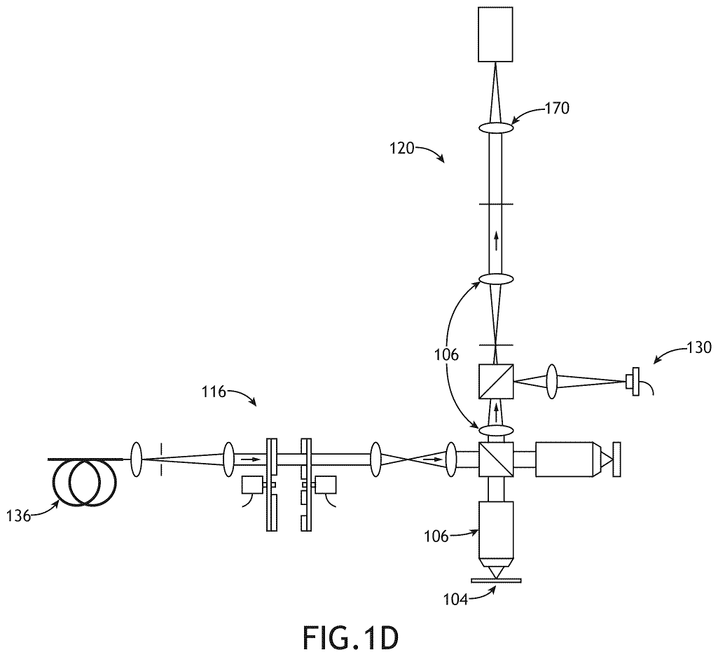

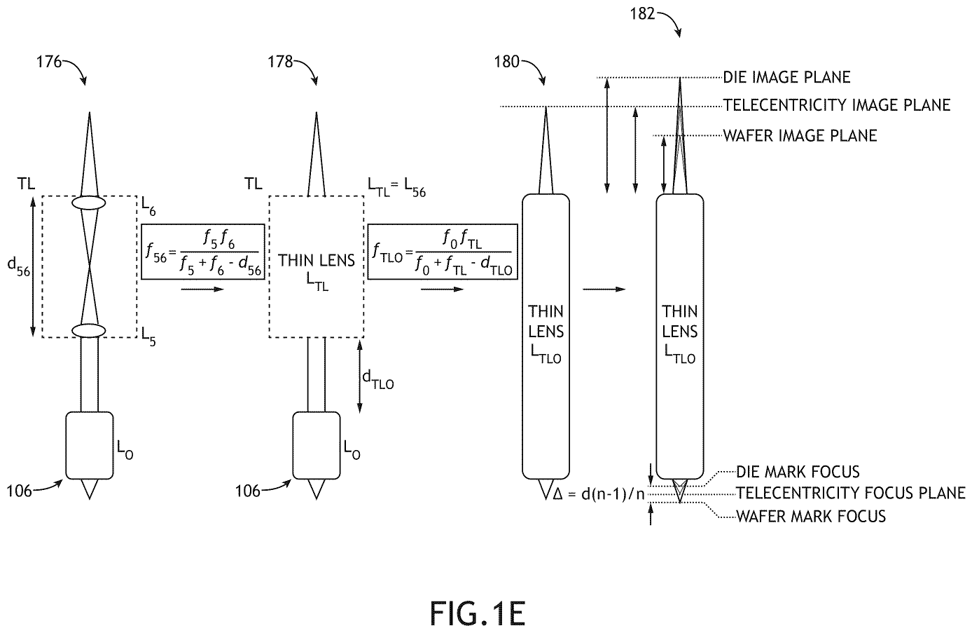

Referring now to FIGS. 1A-5, systems and methods providing tailored imaging of SBS overlay targets for overlay metrology are now described in greater detail, in accordance with one or more embodiments of the present disclosure.

FIG. 1A illustrates a block diagram of an overlay metrology system 100, in accordance with one or more embodiments of the present disclosure.

In embodiments, the overlay metrology system 100 includes an illumination source 102 configured to generate illumination 104, a single objective lens 106 to direct the illumination to an overlay target 108 on a sample 110 and collect light (e.g., sample light 112) from the overlay target 108, and one or more detectors 114 to generate one or more images of the overlay target 108 based on the collected sample light 112.

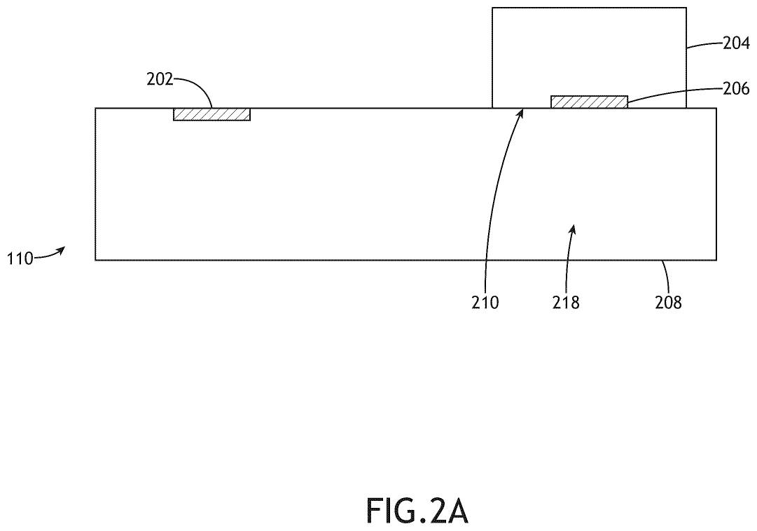

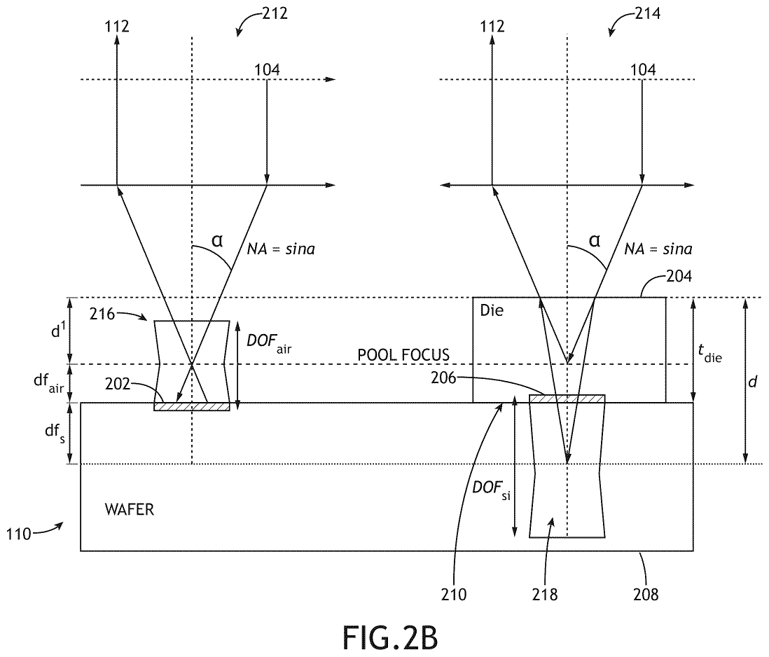

FIG. 2A illustrates a conceptual side view of an overlay target 108, in accordance with one or more embodiments of the present disclosure.

In embodiments, an overlay target 108 includes top-substrate features 202 on a top substrate 204 (e.g., a top substrate) forming a sample 110 and bottom-substrate features 206 on a bottom substrate 208 forming the sample 110, where the top substrate 204 and the bottom substrate 208 are bonded at an interface 210. The top substrate 204 and the bottom substrate 208 may be any type of substrates known in the art that may be bonded to create a bonded sample 110. For example, the sample 110 may be a D2W sample where the top substrate 204 corresponds to a die and the bottom substrate 208 corresponds to a wafer. As another example, the sample 110 may be a W2W sample where the top substrate 204 and the second substrate each correspond to wafers.

In some embodiments, overlay target 108 is a SBS target, where the top-substrate features 202 and the bottom-substrate features 206 are laterally displaced on the 110. For example, FIG. 2A depicts a configuration in which the top-substrate features 202 are located on the bottom-substrate features 206 while the bottom-substrate features 206 are located on the bottom substrate 208 at a location not covered by the top substrate 204. However, this is not a requirement. More generally, the top-substrate features 202 and the bottom-substrate features 206 may at least partially overlap.

The top-substrate features 202 and the bottom-substrate features 206 may generally be at any depth in the respective top substrate 204 and bottom substrate 208. For example, the top-substrate features 202 and/or the bottom-substrate features 206 may be located at or near the interface 210 or buried further within the respective substrate.

The top-substrate features 202 and the bottom-substrate features 206 may have any distribution such as, but not limited to, lines, boxes, ‘L’ shape, or periodic features.

Referring again to FIG. 1A, the overlay metrology system 100 may provide adjustable control of an angular distribution of the illumination 104 directed to the overlay target 108 and/or collected sample light 112 used to generate an image. In this way, properties such as, but not limited to, an illumination NA and/or a imaging NA may be tailored for a measurement of a particular overlay target 108. For example, the overlay metrology system 100 may include an illumination channel 116 with optical elements configured to manipulate the illumination 104 directed to the overlay target 108 such as, but not limited to, an adjustable illumination aperture stop 118 to control a NA or an angular distribution of the illumination 104 more generally. As another example, the overlay metrology system 100 may include at least one collection channel 120 with optical elements configured to manipulate the sample light 112 used for imaging such as, but not limited to, an adjustable collection aperture stop 122 to control an imaging NA or an angular distribution of the sample light 112 more generally.

In some embodiments, the metrology system 100 further includes a controller 124 including one or more processors 126 configured to execute program instructions stored in memory 128 (e.g., a memory device). The processors 126 of the controller 124 may then execute program instructions causing the processors 126 to implement any of the various steps described in the present disclosure either directly or indirectly (e.g., by generating control signals to control components of the overlay metrology system 100 and/or external components). For example, the processors 126 of the controller 124 may receive one or more images from the detector 114. As another example, the processors 126 of the controller 124 may generate one or more overlay metrology measurements of the sample 110 based on the images. As another example, the processors 126 of the controller 124 may generate correctables to control, based on the overlay metrology measurements, one or more process tools such as, but not limited to, a lithography tool, an etching tool, or a polishing tool. Correctables may be generated to control one or more process tools in any combination of a feedback control loop or a feed-forward control loop. As an illustration, feedback correctables generated in response to metrology measurements on a sample 110 may control a process tool during the fabrication of additional samples in the same or different lots (e.g., in response to drifts of the process tools). As another illustration, feed-forward correctables generated in response metrology measurements on a sample 110 may be used to control a process tool during fabrication of additional features on the sample 110 in future process steps.

The one or more processors 126 of a controller 124 may include any processing element known in the art. In this sense, the one or more processors 126 may include any microprocessor-type device configured to execute algorithms and/or instructions. In some embodiments, the one or more processors 126 may consist of a desktop computer, mainframe computer system, workstation, image computer, parallel processor, or any other computer system (e.g., networked computer) configured to execute a program configured to operate the metrology system 100, as described throughout the present disclosure. It is further recognized that the term “processor” may be broadly defined to encompass any device having one or more processing elements, which execute program instructions from a non-transitory memory 128. Further, the steps described throughout the present disclosure may be carried out by a single controller 124 or, alternatively, multiple controllers. Additionally, the controller 124 may include one or more controllers housed in a common housing or within multiple housings. In this way, any controller or combination of controllers may be separately packaged as a module suitable for integration into metrology system 100.

The memory 128 may include any storage medium known in the art suitable for storing program instructions executable by the associated one or more processors 126. For example, the memory 128 may include a non-transitory memory medium. By way of another example, the memory 128 may include, but is not limited to, a read-only memory, a random-access memory, a magnetic or optical memory device (e.g., disk), a magnetic tape, a solid-state drive and the like. It is further noted that memory 128 may be housed in a common controller housing with the one or more processors 126. In some embodiments, the memory 128 may be located remotely with respect to the physical location of the one or more processors 126 and controller 124. For instance, the one or more processors 126 of controller 124 may access a remote memory (e.g., server), accessible through a network (e.g., internet, intranet and the like). Therefore, the above description should not be interpreted as a limitation on the present invention but merely an illustration.

Further, the metrology system 100 may be configurable to generate metrology measurements (e.g., overlay measurements) based on any number of metrology recipes, where a metrology recipe may define various imaging parameters used to generate measurement data and/or processing techniques to generate metrology measurements from measurement data. For example, a metrology recipe may include parameters associated with the illumination 104 such as, but not limited to, incidence angles (e.g., azimuth and/or polar incidence angles), polarization, phase characteristics, or wavelength. As another example, a metrology recipe may include parameters associated with sample light 112 used to generate an image such as, but not limited to, collection angles (e.g., for imaging, where different configurations provide different darkfield and brightfield imaging modes), polarization, phase characteristics, or wavelength. As another example, a metrology recipe may include sampling characteristics such as, but not limited to, locations on a sample 110 to be measured (e.g., locations of overlay targets 108) or focus characteristics. As another example, a metrology recipe may include a measurement mode such as a single grab with single detector 114, a double grab with single detector 114, a single grab with dual detectors 114 or a double grab with dual detectors 114. As another example, the metrology recipe may include the nominal position of an objective lens 106 relative to the sample 110 (e.g., a distance between the objective lens and a top surface of the top substrate 204) at any one of the described measurement modes (e.g., working distances associated with any of the measurement modes).

The overlay metrology system 100 may further include a focusing sub-system 130 to monitor and/or provide data for controlling a position of the sample 110 relative to the objective lens 106 (e.g., a focal distance). The focusing sub-system may include any components or combination of components suitable for monitoring and/or providing data associated with a position of the sample 110 such as, but not limited to, a Linnik interferometer. The Linnik focus interferometry system may be operated either in the time domain or in the frequency domain.

As described throughout the present disclosure, the overlay metrology system 100 may provide tailored control of the angular distributions of the illumination 104 and/or the sample light 112 used for imaging, which may be based at least in part on properties of the top substrate 204 such as, but not limited to, thickness and/or refractive index. Such properties may be received from any source such as, but not limited to, a user, or an external system, or one or more sensors in the overlay metrology system 100. For example, the focusing sub-system 130 may determine a thickness of the top substrate 204 by identifying sample positions associated with top surfaces of the top substrate 204 and bottom substrate 208.

In embodiments, the overlay metrology system 100 is configured to provide simultaneous imaging of both the top-substrate features 202 and the bottom-substrate features 206 on a single detector 114.

FIG. 2B illustrates a variation of FIG. 2A depicting conditions for simultaneous imaging of both the top-substrate features 202 and the bottom-substrate features 206 on a single detector 114 in a single grab (e.g., a single image), in accordance with one or more embodiments of the present disclosure.

It is contemplated herein that imaging both the top-substrate features 202 and the bottom-substrate features 206 on a single detector 114 in a single grab requires that both the top-substrate features 202 and the bottom-substrate features 206 fall within a depth of field of the objective lens 106 (e.g., of the collection channel 120) such that both the top-substrate features 202 and the bottom-substrate features 206 are visible in the image. However, as depicted in FIG. 2B, the optical paths of light associated with imaging the top-substrate features 202 and the bottom-substrate features 206 differ substantially based on the presence of the top substrate 204.

For illustrative clarity, FIG. 2B separately depicts a first imaging path 212 associated with imaging the top-substrate features 202 and a second imaging path 214 associated with imaging the bottom-substrate features 206. For example, the first imaging path 212 and the second imaging path 214 separately depict illumination 104, sample light 112, and the objective lens 106. Both the first imaging path 212 and the second imaging path 214 are thus shown with a separate depth of field and associated focal planes located at central positions of the respective depths of field. However, this is merely for the purposes of illustration and it is to be understood that the top-substrate features 202 and the bottom-substrate features 206 may both be within a field of view of the objective lens 106 and may be simultaneously imaged.

As shown in FIG. 2B, the objective lens 106 may provide a first depth of field 216 associated with propagation in air and a second depth of field 218 associated with propagation in a combination of air and the sample 110 (e.g., the top substrate 204 and potentially the bottom substrate 208). As a result, the first depth of field 216 and the second depth of field 218 may have different lengths and positions.

Simultaneous imaging of the top-substrate features 202 and the bottom-substrate features 206 may thus be achieved by controlling an imaging NA to provide that the top-substrate features 202 fall within the first depth of field 216 and the bottom-substrate features 206 fall within the second depth of field 218. As an illustration, FIG. 2B depicts a configuration in which the top-substrate features 202 fall at or near an bottom portion of the first depth of field 216 while the bottom-substrate features 206 fall at or near a top portion of the second depth of field 218.

The conditions for the imaging NA for single-grab imaging with a single detector may be described using Equation (1):

$$N A = \sqrt{\frac{0.6 λ}{{t}_{s 1}} \cdot \frac{2 {n}_{s}}{{n}_{s} - 1}} \qquad ( 1 )$$

$${d}^{′} = {t}_{s 1} - d {f}_{a i r} = \frac{d}{{n}_{s}} \qquad ( 2 )$$

$$d {f}_{a i r} = \frac{D O {F}_{air , FWHM}}{2} = 0.6 \frac{λ {n}_{a i r}}{N {A}^{2}} \qquad ( 3 )$$

$$d {f}_{s} = d - {t}_{s 1} = \frac{D O {F}_{s , FWHM}}{2} = 0.6 \frac{λ {n}_{s}}{N {A}^{2}} \qquad ( 4 )$$

where NA is an imaging NA (e.g., of sample light 112 used for imaging), α is angle of light, λ is wavelength of the illumination 104, tₛ₁ is a thickness of the top substrate 204, nₛ is refractive index of the sample 110 (e.g., both the top substrate 204 and bottom substrate 208), nₐᵢᵣ is refractive index of air, d′ corresponds to a focus position in air (e.g., a center of the first depth of field 216 corresponding to a focal plane in air), d corresponds to a focus position in the sample 110 (e.g., a center of the second depth of field 218 corresponding to a focal plane in the sample 110), DOF_{air, FWHM} is a length of the first depth of field 216 in air, and DOF_{s,FWHM} is a length of the second depth of field in the sample 110. In some embodiments, the model described by Equation (1) is used as a guide or a starting point for determining an imaging NA. However, it is to be understood that the model described by Equation (1) is merely illustrative and depends on the particular configuration of the overlay target 108, where different configurations may be described by different models.

In some embodiments, the overlay metrology system 100 generates a single image (e.g., a single grab) in which both the top-substrate features 202 and the bottom-substrate features 206 are simultaneously visible by 1) adjusting an imaging NA (e.g., with a collection aperture stop 120) based on Equation (1) based on known or received values of the thickness (tₛ₁) and refractive index (nₛ) of the top substrate 204; and 2) adjusting a position of the sample 110 (e.g., a top surface of the top substrate 204) relative to the objective lens 106 (e.g., a working distance) to provide that the focus position in air (d′) satisfies Equation (2). Alternatively, the focus position in air (d′) may be determined by scanning the sample 110 through focus and calculating the best contrast position for the overlay measurement (or at least an acceptable contrast position) according to any suitable measure of image contrast. For example, the overlay metrology system 100 (e.g., via the controller 124) may evaluate the imaged contrast of the top-substrate features 202 and/or the bottom-substrate features 206 using a contrast metric (e.g., a measure of pixel values associated with the features relative to background signal) for multiple configurations and select a configuration providing a value of the contrast metric higher than a selected threshold value.

As shown by Equations (1)-(4), the conditions for single-grab imaging are critically dependent on the properties of the top substrate 204 (e.g., the thickness and refractive index). In particular, increasing this thickness necessitates a reduction of the maximum imaging NA. However, decreasing the imaging NA may result in a loss of contrast or visibility of the top-substrate features 202 and/or the bottom-substrate features 206.

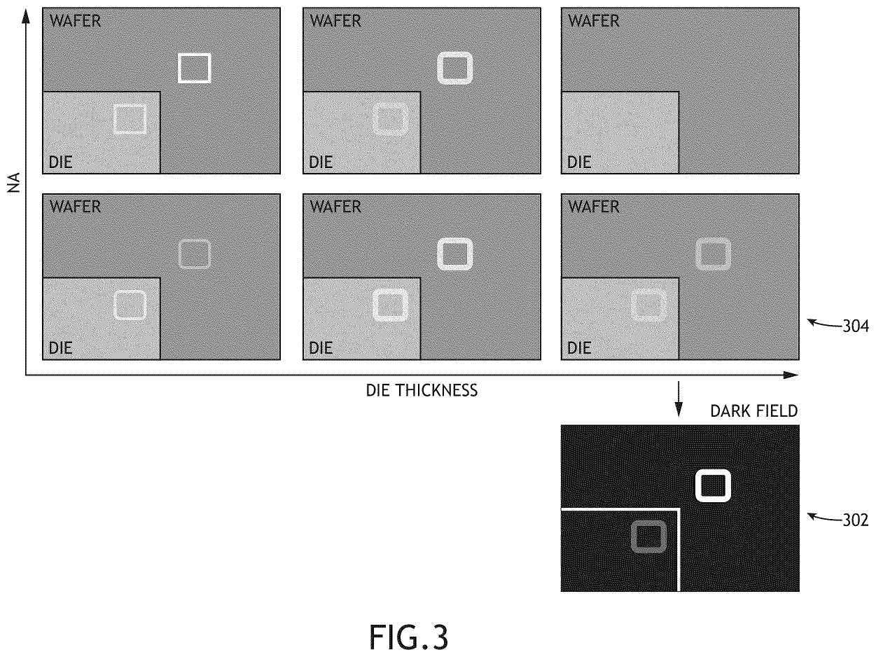

FIG. 3 illustrates a series of schematic diagrams depicting images of top-substrate features 202 and bottom-substrate features 206 of a SBS overlay target 108 as a function of imaging NA and thickness of the top substrate 204 (tₛ₁), in accordance with one or more embodiments of the present disclosure. In each of the schematic diagrams of FIG. 3, the top-substrate features 202 are shown near a corner of the top-substrate features 202 and the bottom-substrate features 206 are shown in an open area near the corner.

Generally, increasing an imaging NA promotes high contrast and sharp imaging. However, as shown above, increasing thickness of the top substrate 204 places limitations on the imaging NA and generally reduces the maximum achievable NA in a single grab configuration. This is depicted in FIG. 3 by the third column of schematic diagrams only showing both the top-substrate features 202 and the bottom-substrate features 206 for relatively lower imaging NA values.

In a general sense, the overlay metrology system 100 may generate images in any imaging configuration including, but not limited to, brightfield imaging or darkfield imaging. It is contemplated herein that darkfield imaging may facilitate higher-contrast imaging than brightfield imaging, particularly when imaging an overlay target 108 with a relatively thick top substrate 204 using a relatively low imaging NA. This is depicted in the schematic diagram 302 of FIG. 3, which represents a darkfield image under the same thickness and imaging NA as shown in the brightfield schematic diagram 304.

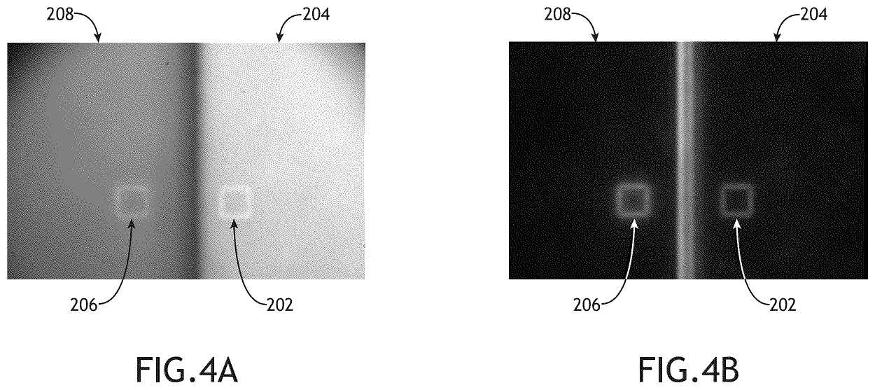

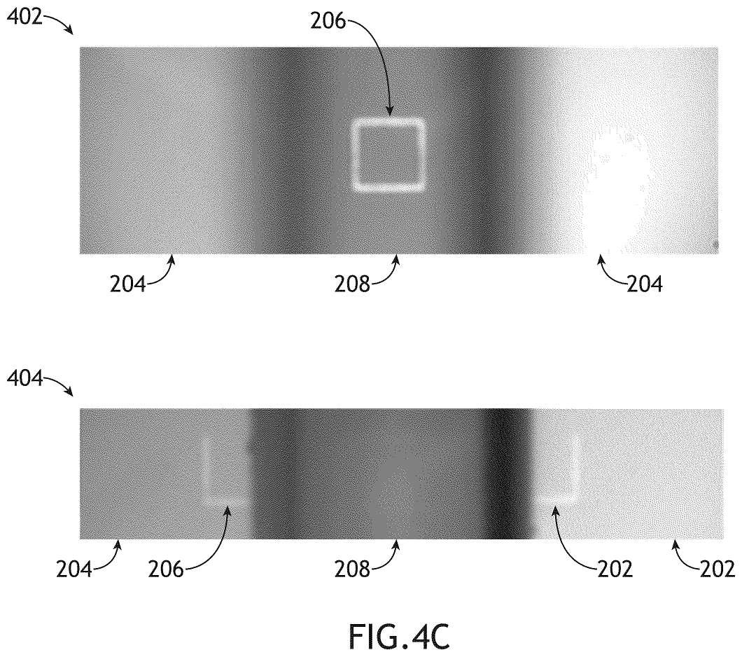

FIG. 4A illustrates a brightfield image of an SBS overlay target 108 generated using a single-grab imaging technique, in accordance with one or more embodiments of the present disclosure. In FIG. 4A, the illumination NA is set to 0.2 and the imaging NA is set to 0.075. Further, the overlay target 108 includes bottom-substrate features 206 formed as a box feature and L-shaped top-substrate features 202 on two first substrates 204.

FIG. 4B illustrates a darkfield image of the same SBS overlay target 108 images in FIG. 4A using a single-grab imaging technique, in accordance with one or more embodiments of the present disclosure. In FIG. 4B, the illumination NA is annular with a NA_{I,min} set to 0.08 and NA_{I,max} set to 0.14, while the imaging NA is set to 0.075. As shown by a comparison of FIG. 4A and FIG. 4B, darkfield imaging may provide substantially higher contrast than brightfield imaging. In some cases, darkfield imaging may improve the precision of an overlay measurement by a 50-500% based on the increased contrast.

However, there may be conditions for which the contrast of the top-substrate features 202 and/or the bottom-substrate features 206 is below an acceptable limit (e.g., according to a contrast metric) under either brightfield or darkfield imaging configurations. Accordingly, in some embodiments, the overlay metrology system 100 is configurable to provide separate images of the top-substrate features 202 and the bottom-substrate features 206 either simultaneously or sequentially. In such double-grab configurations, the imaging planes and/or the imaging NA values may be tailored for the separate images.

FIG. 4C illustrates double-grab imaging of an SBS overlay target 108, in accordance with one or more embodiments of the present disclosure. In FIG. 4C, the SBS overlay target 108 includes bottom-substrate features 206 formed as a box feature and top-substrate features 202 on two top substrates 204. The first image 402 is generated with the bottom-substrate features 206 in focus, while the second image 404 is generated with the top-substrate features 202 in focus. The images in FIG. 4C may be generated either sequentially or simultaneously based on any combination of high-stiffness translation stages.

Referring now to FIGS. 1B-1E, various non-limiting configurations of the overlay metrology system 100 suitable for tailored imaging of an SBS overlay target 108. Each of the configurations in FIGS. 1B-1E may provide brightfield or darkfield imaging in either single-grab or double-grab configurations.

FIG. 1B illustrates a conceptual view of a configuration of the overlay metrology system 100 including a single detector 114, in accordance with one or more embodiments of the present disclosure. FIG. 1C illustrates a conceptual view of a configuration of the overlay metrology system 100 including two detectors 114, in accordance with one or more embodiments of the present disclosure. FIG. 1D illustrates a conceptual view of a configuration of the overlay metrology system 100 providing double telecentric of both object and image space, in accordance with one or more embodiments of the present disclosure.

Referring generally to FIGS. 1B-1D, the illumination source 102 may provide illumination 104 with any wavelength suitable for imaging through the top substrate 204. For example, the illumination source 102 may provide illumination 104 having short-wave infrared (SWIR) wavelengths, which may be suitable for imaging through semiconductor substrates such as, but not limited to, silicon substrates. Further, the illumination 104 may have any bandwidth and may be characterized as narrowband or broadband light. In some embodiments, the illumination source 102 provides illumination 104 with a tunable spectrum, either directly or through spectral filters. For example, FIGS. 1B-1C depict an illumination source 102 with a light source 132 and one or more spectral filters 134 for spectral selection.

The illumination source 102 may include any light source suitable for providing illumination 104 with the selected wavelengths. For example, the illumination source 102 may include one or more laser sources, one or more light emitting diode (LED) sources, or one or more lamp sources.

The illumination source 102 may provide the illumination 104 using any technique including, but not limited to, fiber optics or free-space optics. For example, FIGS. 1B-1C depict a configuration in which the illumination 104 is provided by fiber optics 136. The illumination channel 116 may utilize any type of fiber optics known in the art. In some embodiments, the illumination channel 116 utilizes a multi-mode fiber such as, but not limited to, a square, hexagonal or octagonal core fiber to provide a spatially uniform source of illumination 104.

The illumination channel 116 may include any combination of lenses or other optical elements suitable for directing the illumination 104 to the sample 110 through the objective lens 106. In some embodiments, the illumination channel 116 provides Koehler illumination of the sample 110. Further, the illumination channel 116 may include relay lenses to provide access to an illumination pupil plane 138 and/or an illumination field plane 140. For example, FIGS. 1B-1C depict a Koehler illumination configuration with two lenses 142 to project illumination 104 onto the illumination pupil plane 138 and two lenses 144 to relay the illumination pupil plane 138 to an entrance pupil of the objective lens 106 as well as provide access to the illumination field plane 140.

Various stops may be placed in the illumination pupil plane 138 and/or the illumination field plane 140 to manipulate the illumination 104 directed to the sample 110. For example, an illumination field stop 146 may block stray light from the illumination channel 116 and provide a desired illuminated beam spot. As another example, the illumination channel 116 may include an adjustable illumination aperture stop 118 at the illumination pupil plane 138 to provide adjustable control of the angular profile of the illumination 104 directed to the sample 110. As an illustration, the adjustable illumination aperture stop 118 may provide an adjustable illumination NA without requiring modification of the objective lens 106 (e.g., using a single objective lens 106)

The adjustable illumination aperture stop 118 may include any components suitable for providing adjustable control over the angular profile of the illumination 104. In some embodiments, the adjustable illumination aperture stop 118 is formed as two or more apertures on a translation stage (e.g., a rotational stage, a linear stage, or the like), where different apertures may be selectively placed in the illumination pupil plane 138. In some embodiments, the adjustable illumination aperture stop 118 is formed as an adjustable spatial filter such as, but not limited to, a spatial light modulator.

The adjustable illumination aperture stop 118 may provide any angular profile suitable for any imaging technique. In some embodiments, the adjustable illumination aperture stop 118 provides a circular aperture with a selectable diameter, which may be suitable for brightfield imaging. As a nonlimiting illustration, the adjustable illumination aperture stop 118 may provide a circular aperture with a tailorable illumination NA in a range of 0.05-0.2, where the range is either continually adjustable or provided in steps (e.g., 0.05, 0.075, 0.09, 0.11, 0.14, and 0.2, or any other suitable selection). As another nonlimiting illustration, the adjustable illumination aperture stop 118 provides an annular aperture providing selectable inner illumination NA (NA_{I,min}) and/or outer illumination NA (NA_{I,max}), which may be suitable for darkfield imaging. The adjustable illumination aperture stop 118 may provide any selected range of inner and outer illumination NA values. Nonlimiting examples include NA_{I,min}=0.05 and NA_{I,max}=0.1, NA_{I,min}=0.08 and NA_{I,max}=0.14, or NA_{I,min}=0.14 and NA_{I,max}=0.2.

In some embodiments, the overlay metrology system 100 includes a beamsplitter 148 or other component suitable for providing simultaneous illumination and collection with the objective lens 106. For example, the beamsplitter 148 directs illumination 104 from the illumination channel 116 to the sample 110 and directs collected sample light 112 to the collection channel 120.

Additionally, the beamsplitter 148 may enable the use of a Linnik interferometer as a focusing sub-system 130. For example, the focusing sub-system 130 in FIGS. 1B-1C includes an additional objective lens 150 that is complementary to the objective lens 106 and a reflecting mirror 152. The focusing sub-system 130 further includes a focusing detector 154 arranged to capture interference between the sample light 112 and a portion of the illumination 104 reflected by the reflecting mirror 152 and picked off by an additional beamsplitter 156. Any suitable focusing detector 154 may be used such as, but not limited to, a photodiode or a spectrometer. Linnik interferometry is generally described in U.S. Patent Publication 2024/0035810 published on Feb. 1, 2024; U.S. Pat. No. 12,001,148 issued on Jun. 4, 2024; U.S. Pat. No. 11,713,959 issued on Aug. 1, 2023; U.S. Pat. No. 12,066,322 issued on Aug. 20, 2024; and U.S. Pat. No. 11,629,952 issued on Apr. 18, 2023; all of which are incorporated herein by reference in its entirety. The overlay metrology system 100 may further include a shutter 158 or adjustable blocker to selectively block a light path to the additional objective lens 150 when the focusing sub-system 130 is not in use to prevent interference during a measurement.

In a manner similar to the illumination channel 116, the collection channel 120 may include any combination of lenses or other optical elements suitable for directing the sample light 112 to one or more detectors 114. For example, FIGS. 1B-1C illustrate a collection channel 120 with relay lenses 160 to provide access to a collection pupil plane 162 and/or a collection field plane 164.

Various stops may be placed in the collection pupil plane 162 and/or a collection field plane 164 to manipulate the sample light 112. For example, a collection field stop 166 may block stray light from the collection channel 120. As another example, the collection channel 120 may include an adjustable collection aperture stop 122 at the collection pupil plane 162 to provide adjustable control of the angular profile of the sample light 112 used for imaging without requiring adjustments to the objective lens 106 (e.g., utilizing a single objective lens 106). In a manner similar to the illumination channel 116, the adjustable collection aperture stop 122 may include any components suitable for providing adjustable control over the angular profile of sample light 112 such as, but not limited to, one or more apertures on a translation stage or an adjustable spatial light modulator. Further, the adjustable collection aperture stop 122 may provide various shapes to control the imaging NA such as, but not limited to, an circular aperture (e.g., for either brightfield or darkfield imaging) with an adjustable diameter or an annular aperture (e.g., for darkfield imaging) with adjustable inner and outer diameters.

The overlay metrology system 100 may provide any type of darkfield imaging configuration. For example, there may be two darkfield imaging modes: direct darkfield and reverse darkfield. In reverse darkfield, the overlay metrology system 100 may include an annular ring at the adjustable illumination aperture stop 118 and provide a circular aperture at the adjustable collection aperture stop 122 having an opening diameter slightly smaller than the inner diameter of the ring in the adjustable illumination aperture stop 118. In direct darkfield, the adjustable illumination aperture stop 118 may include a circular aperture and the adjustable collection aperture stop 122 may include an annular ring having its smallest diameter slightly larger than the diameter of the adjustable illumination aperture stop 118.

As non-limiting illustrations, the adjustable collection aperture stop 122 may include a circular aperture with a tailorable imaging NA in a range of 0.05-0.45, where the range is either continually adjustable or provided in steps (e.g., 0.05, 0.075, 0.09, 0.10, 0.11, 0.14, 0.2 and 0.45, or any other suitable selection), which may be suitable for either darkfield or brightfield imaging. As another nonlimiting illustration, the adjustable collection aperture stop 122 provides an annular aperture providing selectable inner imaging NA (NA_{C,min}) and outer illumination NA (NA_{C,max}), which may be suitable for darkfield imaging when configured to block zero-order light. A nonlimiting example includes NA_{C,min}=0.2 and NA_{C,max}=0.45 or NA_{C,min}=0.2 and NA_{C,max}=0.35.

The overlay metrology system 100 may include any number of detectors 114 to provide any number of simultaneous images. For example, FIG. 1B depicts a configuration with a single detector 114, which may be suitable for single-grab imaging (e.g., as depicted in FIGS. 4A-4B) or sequential double-grab imaging (e.g., as depicted in FIG. 4C). As another example, FIG. 1C depicts a configuration with two detectors 114 and associated channel splitting optics 168 (e.g., one or more beamsplitters, or the like), which may be suitable for simultaneous or sequential double-grab imaging (e.g., as depicted in FIG. 4C). The one or more detectors 114 may incorporate any sensor suitable for collecting the sample light 112. For example, a detector 114 may include, but is not limited to, a charge-coupled device (CCD), a complementary metal-oxide-semiconductor (CMOS) device, or a photodiode array. Further, the sensor may be formed from any suitable material. As an illustration a SWIR sensor suitable for SWIR illumination 104 may be formed from materials such as, but not limited to, InGaAs, PbS, PbSe, or InAsSb.

Referring now to FIG. 1D, FIG. 1D depicts a configuration of the overlay metrology system 100 that is substantially similar to FIG. 1B except that the configuration in FIG. 1D is telecentric both in object and image space. For example, the collection channel 120 in FIG. 1D includes an additional tube lens 170.

The overlay metrology system 100 may provide adjustable imaging planes for the generation of one or more images. In some embodiments, the overlay metrology system 100 includes one or more high-stiffness translation stages to position various elements (e.g., along a focal direction, an optical axis, or the like). Any components of the overlay metrology system 100 may be mounted on a high-stiffness translation stage such as, but not limited to, the illumination channel 116, the collection channel 120, the focusing sub-system 130, or the one or more detectors 114. A high-stiffness translation stage may incorporate any stage technology such as, but not limited to, a linear air bearing stage. Further, a high-stiffness translation stage may have any stiffness characteristics suitable for providing a desired level of lateral precision (e.g., precision in a plane orthogonal to a focal direction/optical axis) across a range of motion. For example, such a high-stiffness translation stage may be sufficiently stiff that lateral movement across the range of motion results in systematic and/or non-systematic overlay measurement error smaller than a selected measurement tolerance. As a non-limiting example, the non-systematic crosstalk is in the nm range while the systematic error is in the range of tens of nm.

For example, the configuration of the overlay metrology system 100 in FIG. 1B or FIG. 1D may be implemented by mounting at least the illumination channel 116, the objective lens 106 and the focusing sub-system 130 on a translation stage 172 (e.g., a high-stiffness translation stage). Such a configuration may provide rapid focusing and selection of an imaging plane. Alternatively, the entire optical system may be mounted on a translation stage. As an illustration, single-grab imaging may be performed by selecting the imaging NA based on Equation (1) and setting an imaging plane to the pool focus position d′ in Equation (2) based on known, measured, or received properties of the top substrate 204. The value of d′ may in some cases be determined during a train phase using through focus contrast scan and then used as the nominal objective position at production (HVM). As another illustration, sequential double-grab imaging may be performed by flexibly setting the image planes to the positions of the top-substrate features 202 and the bottom-substrate features 206 with imaging NA values selected to provide a desired contrast (e.g., a contrast value associated with a contrast metric higher than a selected threshold).

As another example, the configuration of the overlay metrology system 100 in FIG. 1C may be implemented by mounting at least the illumination channel 116, the objective lens 106 and the focusing sub-system 130 on a translation stage 172 (e.g., a high-stiffness translation stage) in a manner similar to FIG. 1B or 1D, and further mounting the collection channel 120, the detectors 114 on additional high-stiffness translation stages 174. In this way, the translation stage 172 may set the focal position of the sample 110 relative to the objective lens 106, while the translation stages 174 may provide individually-adjustable imaging planes for the two detectors 114 such that one detector 114 may image the top-substrate features 202 and another detector 114 may image the bottom-substrate features 206. In this configuration, the imaging NA may be adjusted to provide a desired contrast on both detectors 114, which may be larger than the single-grab imaging NA determined by Equation (1).

As an illustration of the operation of the overlay metrology system 100, the controller 124 may calculate virtual focus value based on Δ=tₛ₁ (nₛ−1)/nₛ and set an objective focus distance (e.g., a separation between the sample 110 and the objective lens 106) as Δ/2 above the bottom substrate 208 with a high-stiffness translation stage 172. The controller 124 may then adjust the additional translation stages 174 to separately bring the top-substrate features 202 and the bottom-substrate features 206 into focus on the separate detectors 114.

FIG. 1E illustrates a relationship between image and focus planes in the overlay metrology system 100, in accordance with one or more embodiments of the present disclosure. A first panel 176 depicts the relay lenses 160 in FIGS. 1B-1C. A second panel 178 depicts a thin lens approximation of the relay lenses 160, where a combined focal length may be written as:

$${f}_{56} = \frac{{f}_{5} {f}_{6}}{{f}_{5} + {f}_{6} - {d}_{56}} .$$

A third panel 180 depicts a thin lens approximation of the relay lenses 160 and the objective lens 106, where a combined focal length may be written as:

$${f}_{T L O} = \frac{{f}_{0} {f}_{T L}}{{f}_{0} + {f}_{T L} - {d}_{T L O}} .$$

A fourth panel 182 depicts various focus and image planes. In particular, the panel 182 depicts the nominal position of each detector 114 relative to the principal plane of the tube lens (S_{I,T} and S_{I,B}) and the relationship between the magnification of the system (M), the objective focus (f_{O}) and TL focus (f_{TL}). In this figure, each detector 114 may be positioned

$$\pm \frac{{M}^{2} d ( n - 1 )}{2 n}$$

about the image plane of the single detector configuration. This value may be used as a starting point to search for the best contrast position of each detector 114 (e.g., a contrast value associated with a contrast metric higher than a selected threshold value).

It is noted that the dual detector 114 single grab configuration in FIG. 1C may provide additional flexibility for selecting the imaging NA, but may not be suitable for all situations. For example, the configuration in FIG. 1C may have relatively higher complexity and cost. As another example, the configuration in FIG. 1C may suffer from slight magnification changes and/or telecentricity mismatches between images generated by the two detectors 114, and a 50% reduction in photon budget (e.g., image intensity) on each detector 114 relative to the configuration in FIG. 1B.

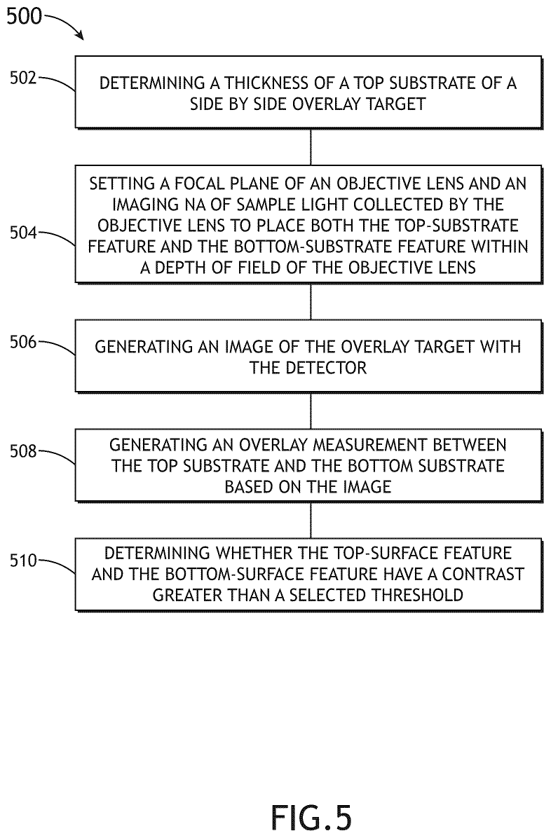

FIG. 5 is a flow diagram illustrating steps performed in an overlay metrology method 500, in accordance with one or more embodiments of the present disclosure. The embodiments and enabling technologies described previously herein in the context of the overlay metrology system 100 should be interpreted to extend to the method 500. For example, the controller 124 may implement one or more steps of the method 500 either directly (e.g., as algorithmic steps) or indirectly by generating control signals that control additional components of the overlay metrology system 100 and/or external components. However, the method 500 is not limited to the architecture of the overlay metrology system 100.

The method 500 may include a step 502 of determining a thickness of a top substrate of a side-by-side overlay target, where the overlay target includes a top-substrate feature on the top substrate and a bottom-substrate feature on the bottom substrate that is laterally displaced from the top-substrate feature in a location not covered by the top substrate. For example, the thickness may be determined by an overlay measurement system, received by a user, or determined by an external sensor.

The method 500 may include a step 504 of setting a position of the object lens relative to the sample (e.g., a distance between the objective lens and a top surface of the top substrate) and an imaging NA of sample light collected by the objective lens to place both the top-substrate feature and the bottom-substrate feature within a depth of field of the objective lens. In some embodiments, the method 500 may set (e.g., select) the focal plane of the objective lens and the imaging NA at values that achieve a selected imaged contrast of the top-substrate feature and bottom-substrate feature. The contrast may be characterized by any contrast metric representative of a visibility of the features such as, but not limited to, a metric indicative of a difference between pixel values associated with the features relative to background areas or other areas. Accordingly, the step 504 may include setting values of the focal plane of the objective lens and the imaging NA that provide a value of a selected contrast metric higher than a selected threshold value.

In some embodiments, the step 504 is performed by setting the values of the focal plane of the objective lens and the imaging NA according to one or more models (e.g., a model associated with Equation (1), or the like) that predict positions that may provide a desired imaged contrast. In some embodiments, the step 504 is performed by evaluating test images generated at multiple configurations (e.g., multiple sample values of the focal plane and imaging NA) to determine suitable values. Further, one or more models may be used as starting positions for the evaluation of test images.

Further, the step 504 is not limited to setting values of the focal plane of the objective lens and the imaging NA and may generally include generating at least a portion of a metrology recipe describing any aspect of illumination or collection of light to form an image such as, but not limited to, an illumination NA, an illumination spectrum, an imaging NA, a collection spectrum, or an imaging mode (e.g., brightfield imaging, darkfield imaging, or the like).

The method 500 may include a step 506 of generating an image of the overlay target with the detector. For example, both the top-substrate feature and the bottom-substrate feature may be visible in the image. Further, the image may be a brightfield image or a darkfield image.

The method 500 may include a step 508 of generating an overlay measurement between the top substrate and the bottom substrate based on the image.

In some embodiments, although not shown, the method 500 may include a step 510 of determining whether the top-surface feature and the bottom-surface feature have a contrast greater than a selected threshold. When this threshold is not satisfied, the method 500 may include a step of separately imaging the top-surface feature and the bottom-surface feature in separate images. In this case, the method 500 may include a step of generating an overlay measurement between the top substrate and the bottom substrate based on the separate images.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A metrology system comprising:
a light source configured to provide illumination;
a single objective lens configured to direct the illumination to an overlay target on a sample and collect sample light from the overlay target, wherein the sample comprises a top substrate and a bottom substrate, wherein the overlay target includes a top-substrate feature on the top substrate and a bottom-substrate feature on the bottom substrate;
an adjustable illumination aperture stop configured to adjust an illumination numerical aperture (NA) of the illumination on the sample;
a detector configured to image the sample based on the sample light, wherein both the top-substrate feature and the bottom-substrate feature of the overlay target are within a field of view of the detector;
an adjustable collection aperture stop configured to adjust an imaging NA of the sample light provided to the detector; and
a controller including one or more processors configured to execute program instructions causing the one or more processors to implement a metrology recipe by:
receiving a thickness of the top substrate;
generating at least a portion of the metrology recipe defining at least a position of the single objective lens relative to the sample, a configuration of the adjustable collection aperture stop, and a configuration of the adjustable illumination aperture stop based on the thickness of the top substrate to simultaneously image the top-substrate feature and the bottom-substrate feature in a single image, where the metrology recipe provides a contrast of the top-substrate feature and the bottom-substrate feature in the single image according to a contrast metric;
receiving an image of the overlay target based on the metrology recipe; and
generating an overlay measurement between the top substrate and the bottom substrate based on the image.

2. The metrology system of claim 1, wherein the one or more processors of the controller are further configured to:
receive one or more additional images of one or more additional overlay targets based on the metrology recipe; and
generate one or more additional overlay measurements of the one or more additional overlay targets based on the one or more additional images.

3. The metrology system of claim 1, wherein generating the metrology recipe comprises:
evaluating two or more test images generated at different values of at least one of the position of the single objective lens relative to the sample, the configuration of the adjustable collection aperture stop, or the configuration of the adjustable illumination aperture stop.

4. The metrology system of claim 3, wherein the two or more test images include at least one brightfield image and at least one darkfield image.

5. The metrology system of claim 4, wherein the single image is a brightfield image.

6. The metrology system of claim 4, wherein the single image is a darkfield image.

7. The metrology system of claim 1, wherein the bottom-substrate feature is laterally displaced from the top-substrate feature.

8. The metrology system of claim 7, wherein the bottom-substrate feature is exposed.

9. The metrology system of claim 8, wherein the bottom-substrate feature is covered by the top substrate.

10. The metrology system of claim 8, wherein the bottom-substrate feature is covered by a dummy substrate.

11. The metrology system of claim 1, wherein the top-substrate feature and the bottom-substrate feature are at least partially overlapping.

12. The metrology system of claim 1, wherein receiving the thickness of the top substrate comprises:
receiving the thickness of the top substrate from at least one of a user, a sensor in the metrology system, or an external system.

13. The metrology system of claim 1, further comprising:
a focus system including an additional lens and an additional detector.

14. The metrology system of claim 13, wherein the focus system includes a Linnik interferometer.

15. The metrology system of claim 13, wherein receiving the thickness of the top substrate comprises:
measuring the thickness of the top substrate from at least one of a user or an external system with the focus system.

16. The metrology system of claim 1, further comprising:
a filter to adjust a spectrum of the illumination.

17. A metrology system comprising:
a light source configured to provide an illumination;
a single objective lens configured to direct the illumination to an overlay target on a sample and collect sample light from the overlay target, wherein the sample comprises a top substrate and a bottom substrate, wherein the overlay target includes a top-substrate feature on the top substrate and a bottom-substrate feature on the bottom substrate;
an adjustable illumination aperture stop configured to adjust an illumination NA (numerical aperture) of the illumination on the sample;
one or more detectors configured to image the sample based on the sample light, wherein both the top-substrate feature and the bottom-substrate feature of the overlay target are within a field of view of the one or more detectors;
an adjustable collection aperture stop configured to adjust an imaging NA of the sample light provided to the one or more detectors;
a linear translation stage to adjust a position of the single objective lens relative to the sample along a focal direction, wherein an imaged lateral motion of the linear translation stage in a plane orthogonal to the focal direction is lower than an overlay measurement tolerance;
a controller including one or more processors configured to execute program instructions causing the one or more processors to implement a metrology recipe by:
receiving a thickness of the top substrate;
generating at least a portion of the metrology recipe defining at least the position of the single objective lens relative to the sample, a configuration of the adjustable collection aperture stop, and a configuration of the adjustable illumination aperture stop based on the thickness of the top substrate to separately image the top-substrate feature and the bottom substrate in a first image and a second image, where the metrology recipe provides a contrast of the top-substrate feature and the bottom-substrate feature in the first image and the second image according to a contrast metric;
receiving the first image and the second image of the overlay target based on the metrology recipe; and
generating an overlay measurement between the top substrate and the bottom substrate based on the first image and the second image.

18. The metrology system of claim 17, wherein the first image and the second image are generated by a single detector of the one or more detectors at different settings of the linear translation stage.

19. The metrology system of claim 17, wherein the one or more detectors comprise a first detector to generate the first image and a second detector to generate the second image, wherein at least one of the first detector or the second detector is mounted on an additional linear translation stage, wherein an imaged lateral motion of the additional linear translation stage in a plane orthogonal to an optical axis is lower than the overlay measurement tolerance.

20. The metrology system of claim 17, wherein generating the metrology recipe comprises:
evaluating test images generated at different values of at least one of the position of the single objective lens relative to the sample, the configuration of the adjustable collection aperture stop, or the configuration of the adjustable illumination aperture stop.

21. The metrology system of claim 20, wherein the test images include at least one brightfield image and at least one darkfield image.

22. The metrology system of claim 21, wherein the first image and the second image are brightfield images.

23. The metrology system of claim 21, wherein the first image and the second image are darkfield images.

24. The metrology system of claim 17, wherein the bottom-substrate feature is laterally displaced from the top-substrate feature.

25. The metrology system of claim 24, wherein the bottom-substrate feature is exposed.

26. The metrology system of claim 25, wherein the bottom-substrate feature is covered by the top substrate.

27. The metrology system of claim 25, wherein the bottom-substrate feature is covered by a dummy substrate.

28. The metrology system of claim 17, wherein the top-substrate feature and the bottom-substrate feature are at least partially overlapping.

29. The metrology system of claim 17, wherein receiving the thickness of the top substrate comprises:
receiving the thickness of the top substrate from at least one of a user, a sensor in the metrology system, or an external system.

30. The metrology system of claim 17, further comprising:
a focus system including an additional lens and an additional detector.

31. The metrology system of claim 30, wherein the focus system includes a Linnik interferometer.

32. The metrology system of claim 30, wherein receiving the thickness of the top substrate comprises:
measuring the thickness of the top substrate from at least one of a user or an external system with the focus system.

33. The metrology system of claim 17, further comprising:
a filter to adjust a spectrum of the illumination.

34. The metrology system of claim 17, wherein the linear translation stage comprises:
an air bearing stage.

35. A metrology method comprising:
illuminating an overlay target on a sample with an objective lens with an illumination, wherein the sample comprises a top substrate and a bottom substrate, wherein the overlay target includes a top-substrate feature on the top substrate and a bottom-substrate feature on the bottom substrate that is laterally displaced from the top-substrate feature in a location not covered by the top substrate;
determining a thickness of the top substrate;
setting a focal plane of the objective lens, an illumination NA (numerical aperture) of the illumination, and an imaging NA of sample light collected by the objective lens and directed to a detector for imaging the sample to place both the top-substrate feature and the bottom-substrate feature within a depth of field of the objective lens;
generating an image of the overlay target with the detector; and
generating an overlay measurement between the top substrate and the bottom substrate based on the image.

36. The metrology method of claim 35, wherein generating the image of the overlay target with the detector comprises:
generating the image as a brightfield image.

37. The metrology method of claim 35, wherein generating the image of the overlay target with the detector comprises:
generating the image as a darkfield image.
